(19) United States
(12) Patent Application Publication
(10) Pub. No.: US 2013/0200883 A1
(43) Pub. Date: Aug. 8, 2013

(54) MAGNETIC FIELD SENSOR

(71) Applicants: Walter Mehnert, Ottobrunn (DE); Thomas Theil, Feldafing (DE)

(72) Inventors: Walter Mehnert, Ottobrunn (DE); Thomas Theil, Feldafing (DE)

(21) Appl. No.: 13/751,586

(22) Filed: Jan. 28, 2013

(30) Foreign Application Priority Data
Jan. 27, 2012 (DE) 10 2012 001 501.1
Feb. 7, 2012 (DE) 10 1012 022 204.2

(51) Int. Cl. G01R 33/07

(52) U.S. Cl. CPC G01R 33/072
USPC 324/207.2

(57) ABSTRACT

A magnetic field sensor for a position transducer having processing and control electronics for outputtomg signals of the magnetic field sensor and a permanent magnet exciter array has at least three Hall elements for registering the magnetic field direction of the permanent magnet array. The Hall elements are formed and arranged on a semiconductor IC and spaced in such a manner that their active surfaces lie in a common plane parallel to the surface of the semiconductor IC. A single deflecting body made of ferromagnetic material is is produced and installed as an independent component separate from the semiconductor IC, and the mutual distances of the Hall elements on the surface of the semiconductor IC comprise a multiple of the maximum dimensional extent of the Hall elements.

### BACKGROUND OF THE INVENTION

1. Field of the Invention

The invention relates to a magnetic field sensor of the type having at least three Hall elements for a position transducer, processing and control electronics for the output signals of the magnetic field sensor and a permanent magnet exciter array, the magnetic field direction of which is to be detected by means of the Hall elements, such Hall elements being formed and located with mutual distances on a semiconductor integrated circuit (IC) such that their active surfaces lie in a common plane parallel to the upper surface of the semiconductor IC, and with one single deflecting body made of a ferromagnetic material, arranged such that field lines emanating from the permanent magnet array, which, in the absence of the deflecting body, would run parallel to the common plane of the active surfaces of the Hall elements, receive at least one directional component perpendicularly penetrating these active surfaces.

2. Description of Related Art

Of particular suitability as position transducers, are rotary position sensors, by means of which the angular position of a rotating body may be captured. For this purpose, the rotating body is fixed to or coupled with a permanent magnet exciter array, the magnetic field of which precisely reproduces the rotation of the body. The current direction of this magnetic field is detected by means of three Hall elements which are in a fixed position relative to the rotation of the body to be monitored. At least two approximately periodic measurement signals are derived from the output signals of the Hall elements; these measurement signals are phase-shifted to eliminate the ambiguity inherent to each of these two signals.

Magnetic field sensors suitable for this purpose are known from European Patent Application EP 1 182 461 A1, in which the Hall elements are formed and arranged in a semiconductor integrated circuit in such a way that their active surfaces lie in a common plane parallel to one of the plane surfaces of the semiconductor IC. In many applications, it is expedient for structural reasons to orient the permanent magnet exciter array so that its direction of magnetization moves in a plane which is parallel to one of those of the active surfaces of the Hall elements. In order to assure that their active surfaces are nonetheless penetrated by perpendicular components of the magnetic field, at least one deflecting body of a ferromagnetic material is envisioned, shaped and positioned in such a way that a portion of the magnetic field lines emanating from the permanent magnet exciter array which, in the absence of the deflecting body, would run parallel to the active surfaces of the Hall elements, instead penetrates the surfaces with a perpendicular component.

The magnetic field sensors known from the aforementioned publications suffer from some difficulties, as it is assumed that, for a precise measurement of the particular angular position, the at least two measurement signals derived from the output signals of the Hall elements are sinusoidal in an approximation as good as possible.

In addition, the influence of interfering outside magnetic fields on the measurement signals must largely be eliminated. To this end, according to prior art, the four Hall elements are connected in opposite pairs on the semiconductor IC in such a way that the useful field components are added together, while the interference field components are subtracted from one another. However, the interference field components are only equal and thus cancel one another when the interference field penetrates the two Hall elements of each pair with the same strength and in the same direction. With any deviation from these ideal conditions, an interference field portion influencing the measurement result remains, which may increase the farther the active surfaces of the Hall elements are located from one another.

Furthermore, in the named prior art, it is necessary that the deflecting body described therein as a field concentrator be positioned as precisely and symmetrically as possible with regard to the Hall elements, as sine/cosine signals are required as measurement signals. Basically, this can only be achieved by means of applying this deflecting body directly to the surface of the IC using a technology compatible with the production of ICs.

It is a disadvantage in this context that only a very few ferromagnetic materials are suited for application in a very thin layer with a thickness in the order of 15 μm to 30 μm. However, such thin ferromagnetic bodies may only have small dimensions parallel to the direction of the magnetic field to be deflected, as they will otherwise rapidly become saturated.

The fixed application of the deflecting body to the surface of the integrated circuit, which is fixed relative to the rotating magnetic field during the measurement operation, also has as a consequence that a constant magnetic reversal is occurring. The associated hysteresis leads to errors in the measurement signals, which are supposed to be minimized by the deflecting body having a low remanent field strength. However, these errors may not be completely eliminated even with the use of magnetic glasses, which again can only be produced in thin layers.

For all of these reasons, the prior art requires that the Hall elements be located as close to one another as possible on the semiconductor IC; this has the effect that they capture only a very small area of the magnetic field, creating a particular sensitivity to field inhomogenities. In addition, the extremely small arrangement requires that the material of the deflecting body have a high relative permeability μ_{R} in order to generate a sufficiently high field strength concentrated on the Hall elements. However, for a comparable coercive field strength, a large μ_{R} results in a large remanence.

### SUMMARY OF THE INVENTION

Therefore, a primary object of the present invention is the creation of a magnetic field sensor of the type stated above in which all of the above noted problems are avoided.

To accomplish this object, the invention produces and installs the deflecting body as an independent component separate from the semiconductor IC, and the mutual distances of the Hall elements on the surface of the semiconductor IC comprise a multiple of the maximum extent of the Hall elements themselves.

In accordance with the invention, two characteristics of the magnetic field sensor are omitted that were considered indispensable in the prior art, namely the positioning of the deflecting body directly on the surface of the IC, implicating the necessity of producing it with the aid of a process compatible with the IC technology, and the extremely small intervals between the Hall elements on this surface.

This creates a series of advantageous degrees of freedom in constructing the magnetic field sensor.

The deflecting body may be designed to have not only a greater area, but to be significantly thicker than in the prior art, thus reducing the danger of rapid saturation. This permits the use of larger and thus stronger permanent magnets, making it possible to produce the deflecting body from a material with significantly lower relative permeability μ_{R} than in the prior art.

By severing the tie with an IC technology-compatible process for production of the deflecting body, more convenient materials such as, e.g., the Heusler alloy, ferrites, or plastic-bonded ferrites may be used, and specifically those with low remanence and low coercive strength resulting in low hysteresis errors. Ferrites additionally possess the inestimable advantage that their ground particles in the size range of 2 μm are individual single-range grains which, with by their inherent magnetic structure, produce only hysteresis noise when the magnet is rotating, which is naturally significantly smaller than the remanence break otherwise resulting. “Hysteresis noise” is used here to denote the statistical appearance of the remanence breaks of the individual grains.

A key aspect of the invention is that that, due to the greater intervals between the Hall elements, the deflecting body covers a greater surface and therefore acts not only as a field concentrator and symmetrizer, but also in a sense as a field integrator, making the array less sensitive to field inhomogenities.

If, for maximum precision, a hysteresis-free measurement is desired, the physical separation of IC and deflecting body according to the invention permits the deflecting body to be mounted in such a way that it rotates along with the body to be monitored, and thus also with the permanent magnet array. The field penetrating it thus does not change, and no magnetic reversal occurs.

The the positioning accuracy of the deflecting body with respect to the Hall elements is reduced by the measures in accordance with the present invention, causing the measurement signals derivable from the Hall element signals to deviate significantly more from the sinusoidal form and a phase shift value of 90°, is not really a drawback, since the method for acquiring and processing the Hall element signals that may be gleaned from DE 10 2010 010 560.0 A1, which method is ideally employed in conjunction with a magnetic field sensor according to the invention, requires only the reproducibility of semi periodic, otherwise arbitrary sensor signals for obtaining a highly precise measurement, and no longer that they trace an almost perfectly exact sinusoidal path, nor that they be phase shifted precisely by 90°. Instead, the sensor is used there only as an address generator, the memory of which is loaded with the exact measurement values in a calibration run conducted with the aid of a highly accurate position reference standard. The technical contents of DE 10 2010 010 560.0 A1 are hereby incorporated in their entirety by reference.

The invention shall hereafter be described in detail with reference to exemplary embodiments and the accompanying drawings.

### BRIEF DESCRIPTION OF THE DRAWINGS

FIG. 1 is a schematic sectional view of a rotary position sensor, which comprises a magnetic field sensor in accordance with the invention and has a fixed deflecting body in order to capture the angular position of a shaft; and

FIG. 2 is a schematic sectional view of a rotary position sensor similar to that of FIG. 1, but where the magnetic field sensor has a deflecting body rotating with the shaft.

### DETAILED DESCRIPTION OF THE INVENTION

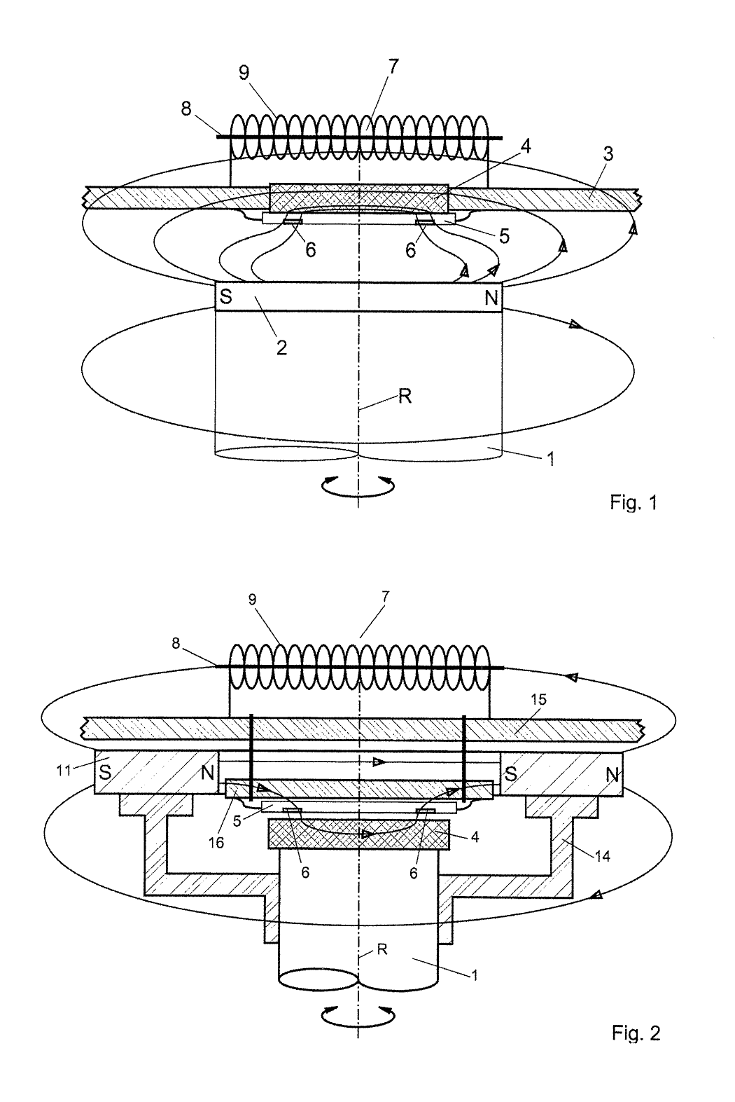

It is hereby explicitly pointed out that FIGS. 1 & 2 are not to scale, and that both the size of the individual components as well as the spacing between them is, in part, significantly magnified for reasons of clarity. Identical components or those corresponding to one another are labeled with the same reference numbers.

The schematic representations of FIGS. 1 & 2 depict the material components of a position transducer which, being a so-called multi-turn sensor, can both finely resolve the individual rotations of a shaft 1 as well as count their absolute number.

In both cases, the shaft 1 may be either the rotating body itself which the rotary position sensor is intended to monitor, or it may be rigidly attached or mechanically coupled to this body in such a manner that it precisely reflects its rotary motion.

A rod-shaped permanent magnet 2 is mounted on the upward facing front end of shaft 1 in FIG. 1 in such a manner that it rotates with shaft 1, wherein the axis of rotation R runs perpendicularly through the middle between its north and south poles.

Above the permanent magnet, also perpendicular to the axis of rotation R, extends a board 3 made of nonmagnetic material and having a through opening in the area above the front end of shaft 1, in which is inserted a planar deflecting body 4 of ferromagnetic material having a greater thickness in the direction of the axis of rotation R than does the plate 3.

Alternatively, the opening may also be a blind hole. The planar deflecting body may also be of annular shape.

The upper side of the housing of an IC semiconductor component 5 is situated adjoining the planar, flat side of the deflecting body 4 facing the front end of shaft 1.

Four Hall elements are formed in the downward-facing surface of the IC semiconductor component 5, of which only two Hall elements 6, 6 are visible in the sectional view of FIG. 1, while a third Hall element is located behind and a fourth in front of the plane of the drawing.

As can be seen, some of the magnetic field lines running from the north to the south pole of the permanent magnet 2 are deflected by the ferromagnetic deflecting body 4, which has a low magnetic resistance, in such a manner that they penetrate the four Hall elements 6 with a perpendicular component, the magnitude of which changes in dependence of the angle of rotation as the shaft 1 and permanent magnet 2 are rotated with respect to the fixed plate 3, so that the signals emitted by the four Hall elements 6 can be used for the high-resolution detection of the angle of rotation of shaft 1.

On its upper surface, the plate 3 bears a Wiegand interface module 7, which is composed of, in its essentials, a Wiegand wire 8—here arranged horizontally—and a coil 9 wound around it. This Wiegand interface module 7 serves, in known manner, to emit signal impulses by means of which the rotations of the shaft 1 may be counted. These signal impulses additionally contain sufficient electrical energy to provide the electrical operating energy at least for that portion of the processing electronics which is necessary for performing the counting operation and for storing the count value attained in the event that the external energy supply fails (e.g., through the disconnection of a battery).

This arrangement is chosen so that the four Hall elements 6 are located as close to the permanent magnet 2 as possible, so that they are penetrated by a strong field resulting in high output signals, while the Wiegand module 7 is located in the area of the significantly weaker far field of the permanent magnet 2 in order to prevent the saturation of the Wiegand wire 8.

The key to this arrangement is that the deflecting body 4, which completely covers the four Hall elements 6, is positioned between the Hall elements 6 and the Wiegand wire 8, so that, in consequence of its high magnetic conductivity, it almost short-circuits the magnetic field of the Wiegand wire 8, and thus, largely protects the four Hall elements 6 against interference from this magnetic field.

If, in the disposition shown in FIG. 1, a particular type of deflecting body 4 is arranged in a fixed manner, it is constantly subjected to reversal of magnetism by the rotation of the permanent magnet 2. Unavoidably, hysteresis occurs, resulting in the appearance of breaks in the signals derived from the output signals of the Hall elements that serve to determine the exact angular position. These breaks may be minimized by selection of a material for the deflecting body 4 having a very low remanence and very low coercive force, but they nonetheless limit the maximum precision attainable with such a position transducer. With the use of ferrites in accordance with the invention, these breaks, the effects of which upon the precision of the measurement are minimal, in any case, are slurred by the hysteresis noise.

If one wishes entirely to avoid such adverse effects of the measurement signals resulting from the hysteresis or hysteresis noise of the material of the deflecting body 4, one may select a configuration in accordance with FIG. 2, in which the deflecting body 4 is fixedly attached to the front end of the rotating shaft 1, so that it rotates along with it, and with a permanent magnet array formed here by a diametrically magnetized permanent magnet ring 11, which is connected fixed to shaft 1 by means of a bracket 14. The directions of magnetization of magnet ring are aligned with one another and extend perpendicularly relative to the axis of rotation R, which runs through the center of the space between the inner north pole of the permanent magnet ring 11 and the opposing inner south pole of the same permanent magnet. In place of a permanent magnet ring, two separate magnets may also be used.

Here, too, a base plate 15 is provided, the axial distance of which from the front end of the shaft 1 is greater than that of the permanent magnet ring 11. The plate 15 carries an auxiliary plate 16 of nonmagnetic material on its underside facing the shaft 1. The IC semiconductor chip 5 (depicted without its housing) is situated on the underside of auxiliary plate 16, and in the surface of auxiliary plate 16 that faces the shaft 1, and thus, faces the deflecting body 4, four Hall elements 6 are formed of which only two Hall elements are depicted here.

Magnetic field lines from the central field of the permanent magnet ring 11 are deflected by the deflecting body 4 in such a manner that they penetrate the four Hall elements 6 approximately perpendicularly.

While care must be taken with a fixed deflecting body 4 that, in order to achieve small hysteresis errors, the remanence and thus μ_{R} is small, a high μ_{R} being desired for a rotating deflecting body in order to suction off a strong field as perpendicularly as possible and to homogenize and allow to escape vertically those external interference fields entering through the shaft 1 which cannot be eliminated. It is particularly advantageous here if the axial distance of the four Hall elements 6 from the deflecting body 4 is kept as small as possible.

Here, too, a Wiegand interface module 7 is envisioned, comprising a Wiegand wire 8 and the coil 9 wound around it, and serving to count the rotations of the shaft 1. As in the exemplary embodiment of FIG. 1, the Wiegand interface module, in this case, is also located in the significantly weaker far field of the permanent magnet ring 11.

Fundamental to both embodiments is that the active surfaces of the four Hall elements 6, as viewed from above the IC upper surface, each have an approximately square footprint, and together are located in a plane at the four corners of a square, the edge lengths of which comprise a multiple of the edge lengths of the active surfaces.

In both cases, the vertical projection of the deflecting body 4 in the direction of the axis of rotation R on the plane of the active surfaces of the four Hall elements 6 is larger than that of the square they form, and covers this symmetrically and completely. For the rotary encoder depicted in FIG. 1, the aforementioned vertical projection may have any symmetrical footprint, e.g., a square footprint, while, in the case of the rotary encoder in FIG. 2, it is of circular or annular shape.

What is claimed is:

1. Magnetic field sensor, comprising:
at least three Hall elements for a position transducer, the Hall elements being formed and located with mutual distances on a semiconductor integrated circuit such that their active surfaces lie in a common plane parallel to an upper surface of the semiconductor integrated circuit,
processing and control electronics for outputting signals of the magnetic field sensor,
a permanent magnet exciter array, a magnetic field direction of which is to be detected by means of the Hall elements, and
a single deflecting body made of a ferromagnetic material, arranged such that field lines emanating from the permanent magnet exciter array, which, in the absence of the deflecting body, would run parallel to the common plane of the active surfaces of the Hall elements, receive at least one directional component perpendicularly penetrating the active surfaces,
wherein the deflecting body is produced and installed as an independent component separate from the semiconductor integrated circuit, and that the mutual distances of the Hall elements on the surface of the semiconductor integrated circuit are a multiple of a maximum dimensional extent of the Hall elements themselves.

2. Magnetic field sensor in accordance with claim 1, wherein the deflecting body is plate-shaped and arranged in such a manner that it has a planar surface that faces the surface of the semiconductor that bears the Hall elements runs approximately parallel thereto.

3. Magnetic field sensor in accordance with claim 1, wherein the plate-shaped deflecting body is arranged on a housing of the semiconductor integrated circuit.

4. Magnetic field sensor in accordance with claim 2, wherein the planar surface of the plate-shaped deflecting body that faces the surface of the semiconductor integrated circuit completely covers the active surfaces of the Hall elements.

5. Magnetic field sensor in accordance with claim 4, wherein the surface of the plate shaped deflecting body facing the surface of the semiconductor integrated circuit completely covers the surface of the semiconductor integrated circuit.

6. Magnetic field sensor in accordance with claims 2, wherein the plate-shaped deflecting body is located in an opening in a plate bearing electronic components of the magnetic field sensor.

7. Magnetic field sensor in accordance with claim 1, wherein the deflecting body has a thickness of at least 0.2 mm in a direction perpendicular to the surface of the semiconductor integrated circuit.

8. Magnetic field sensor in accordance with claim 1, wherein the deflecting body is made of a material that has a low remanence.

9. Magnetic field sensor in accordance with claim 1, wherein the deflecting body is made a material which has a low coercive force.

10. Magnetic field sensor in accordance with claim 1, wherein the deflecting body is made of ferrite.

11. Magnetic field sensor in accordance with claim 1, wherein the sensor is constructed as a rotary position transducer to detect angular position of a rotating shaft, wherein a permanent magnet exciter array is mounted symmetrically to an axis of rotation of the rotating shaft so as rotate with the shaft.

12. Magnetic field sensor in accordance with claim 11, further comprising a Wiegand interface module arrange for determining the absolute number of rotations of the shaft.

13. Magnetic field sensor in accordance with claim 12, wherein the deflecting body is arranged in a fixed manner with respect to the semiconductor integrated circuit between a plane of active surfaces of the Hall elements and the Wiegand interface module in order to short-circuit a field of the Wiegand module which would otherwise interfere with the Hall elements.

14. Magnetic field sensor in accordance with claim 12, wherein the deflecting body is mounted on the rotating shaft in such a manner that it rotates along with the shaft, wherein a vertical projection of the deflecting body onto the surface of the semiconductor integrated circuit bearing the Hall elements is circular in shape.
